(19) United States
(12) Patent Application Publication
(10) Pub. No.: US 2005/0280353 A1
(43) Pub. Date: Dec. 22, 2005

(54) Method for manufacturing electro-luminescence display and electro-luminescence panel utilizing the same

(75) Inventor: Wein-Town Sun, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/135,956

(22) Filed: May 24, 2005

(30) Foreign Application Priority Data
Jun. 21, 2004 (TW) 93117895

(51) Int. Cl. H05B 33/08

(52) U.S. Cl. 313/500; 313/505

(57) ABSTRACT

A method for improving uniformity of displays is provided. The method comprises forming a pixel array comprising a plurality of driving transistors, wherein not all of the driving transistors in the pixel array are of the same standard size. At least two driving transistors of different sizes are connected to the same power supply line.

### BACKGROUND

The invention relates to methods for manufacturing a display and, in particular, to implement uniform current of display with varying driving transistors.

Organic light emitting diode (OLED) displays are currently developed. As shown in FIG. 1A, each pixel in an OLED display comprises a scan line 102, a data line 104, power lines V_{dd} and Vₛₛ, a switch transistor T_{SW}, a driving transistor T_{dr}, a storage capacitor Cₛ and an electro-luminescence (EL) device 110. In most applications, the switch T_{SW} and the driving transistor T_{dr} are thin film transistors (TFTs). While the driving transistor T_{dr} is typically a PMOS transistor in FIG. 1A, it can be a NMOS transistor if the pixel structure is modified, as shown in FIGS. 1B and 1C.

Since the brightness of an OLED is proportional to the current conducted thereby, current variation directly influences display uniformity. In addition, V_{dd} voltage drop between pixels also results in non-uniformity. The reason is that metal resistance generates voltage drop such that voltage potential at different locations along the metal line differs. As shown in FIG. 2, the pixels in a column are typically connected to the same V_{dd} power line. The V_{dd} power lines of all columns are also connected outside the pixel array. For pixels in one column, displaying a common image, a pixel voltage must be written to the gate node 202 of a driving transistor in each pixel. Ideally, equal current flows from the power line through the OLED in each pixel, providing correspondingly equal brightness. However, voltage of the OLED in each pixel differs due because of the aforementioned voltage drop. Thus, voltage difference is generated between the gate and source of each driving transistor, resulting in varying brightness of different pixels.

An embodiment of a method for manufacturing a display comprises forming a power line on a substrate; forming a plurality of driving transistors electrically connected to the power line, wherein the driving transistors in a column are connected to one of the power lines and not all of the channel sizes of the driving transistors in the column are the same. In other words, at least two driving transistors of different channel sizes are connected to the same power line.

Also provided is a panel, comprising a pixel array and each pixel thereof comprises a driving transistor. In the pixel array, driving transistors are of different channel sizes, with at least two connected to the same power line.

### BRIEF DESCRIPTION OF THE DRAWINGS

FIGS. 1A-1C are schematic diagrams of a conventional pixel circuit in an OLED display.

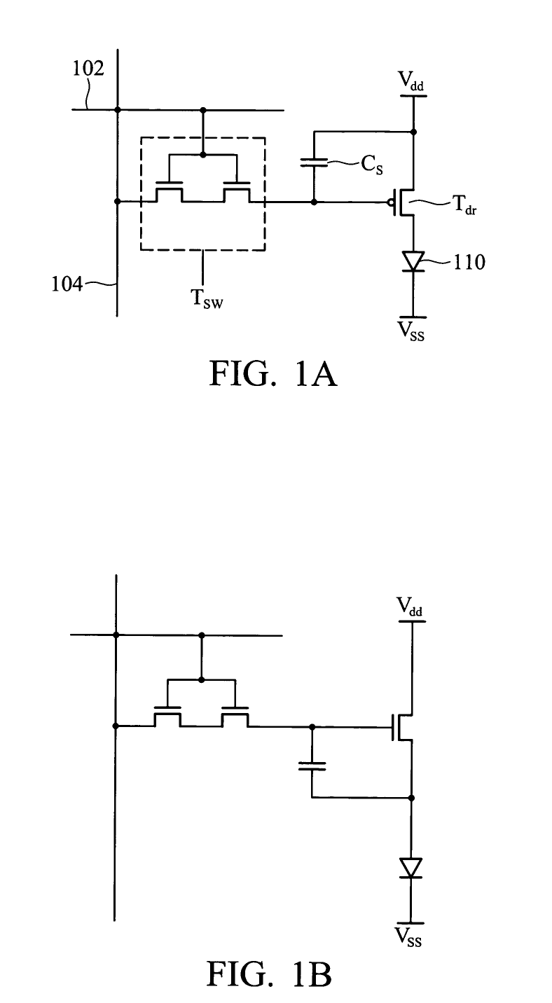

FIG. 2 shows uniformity variations in a conventional OLED display.

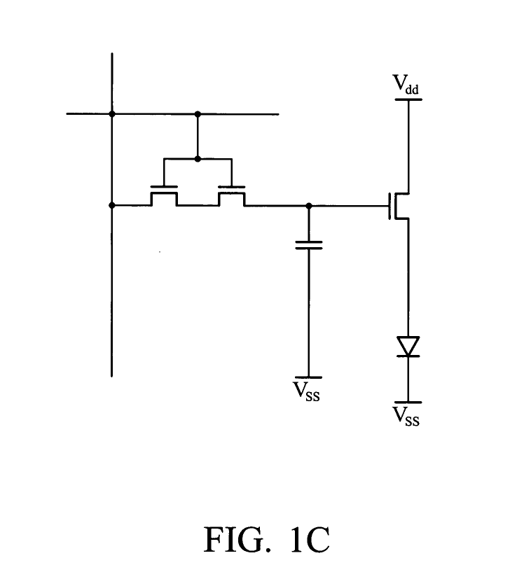

FIG. 3 is a schematic diagram of equivalent circuits of pixel circuits in a column.

FIG. 4 shows V_{dd} voltage corresponding to pixel location when all driving transistors are of same channel size.

FIG. 5 shows simulated results of varying driving transistor channel size with pixel location according to embodiments of the present invention.

FIG. 6 illustrates simulation results of current variation with pixel location at a different gray scale according to one embodiment of the present invention.

### DETAILED DESCRIPTION

While an OLED panel is used as an example in the disclosure of methods of driving a display, the scope of the method is not limited thereto, being equally applicable to any electro-luminescent panel.

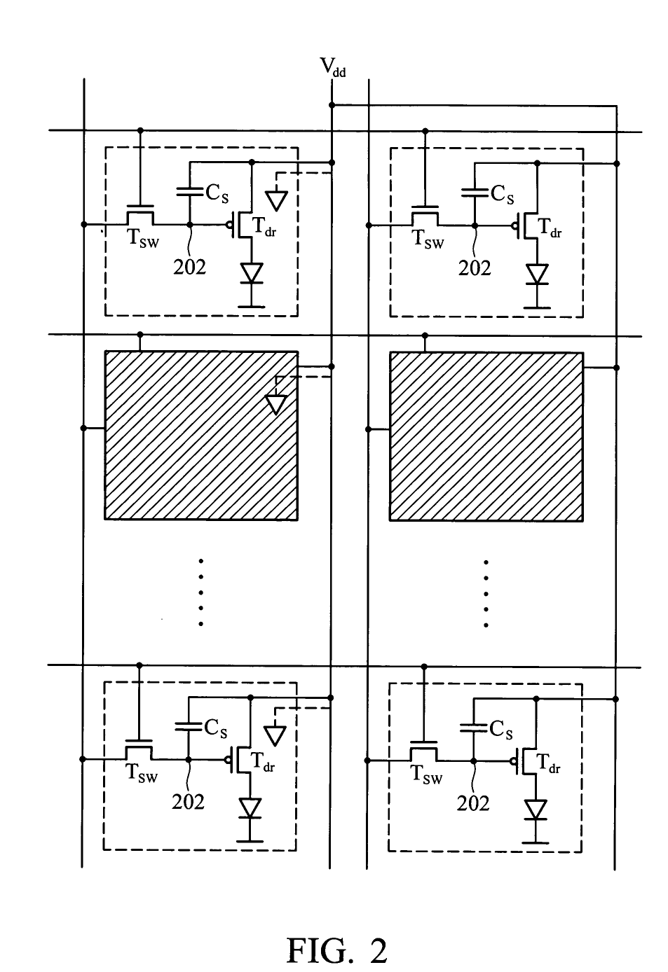

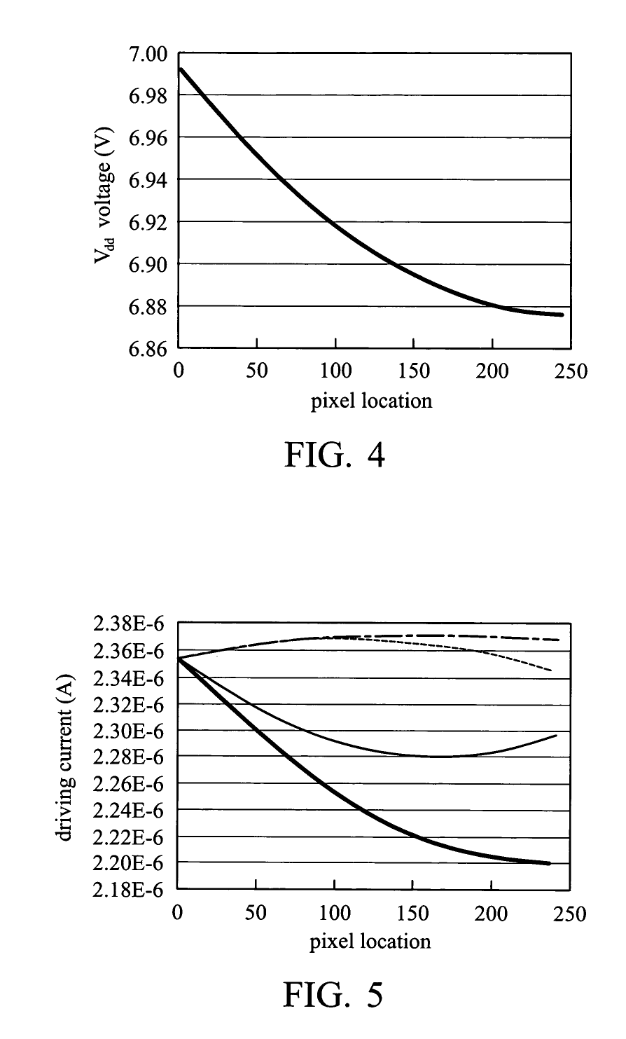

An embodiment of a method for manufacturing a display comprises adjusting the channel widths of driving transistors in a column with the location thereof. The equivalent circuit of a pixel is depicted in FIG. 3. Here, voltage provided through the V_{dd} power line is 7 volts and the channel width of each driving transistor T_{dr}_{_{—}}₁˜T_{dr}_{_{—}}_{N} in the same column changes linearly from the first to the 240^{th} pixel. For example, if the channel width and length of the first driving transistor are 24 μm and 6 μm, respectively, voltage at the cathode of the OLED is a −4 volt. The pixel voltage Vₚᵢₓₑₗ applied into the gate node of a driving transistor in each pixel is 2 volts. The resistance R_{PL} of the power line is 0.918 Ω. Since the V_{dd} power line voltage drops 6.58%, channel width accordingly increases 6.58%. As shown in FIG. 5, the thin solid curve shows current still dropping from about 2.36 μA to 2.2 μA. The current variation is slightly compensated.

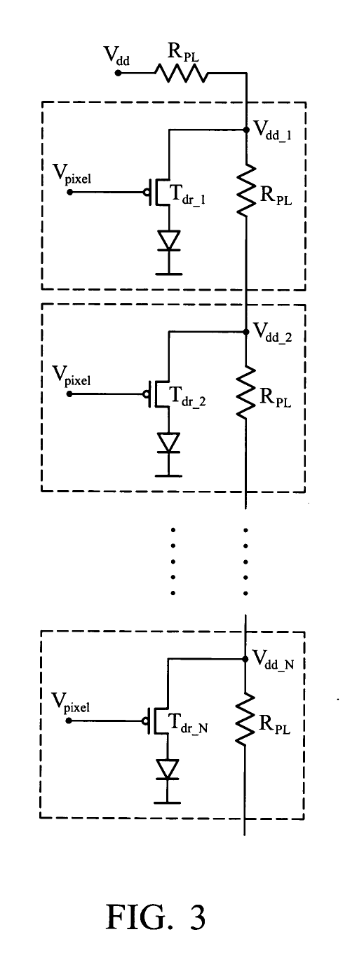

To more accurately compensate for the voltage drop, the curve, standing for the V_{dd} voltage changing with pixel location, in FIG. 4 is approximated as a quadratic equation:
V_{dd}(x)=2·10⁻⁶x²−10⁻³x+6.9944≈2·10⁻⁶x²−10⁻³x+7

If kink effect is not taken into account, the driving current flowing through the driving transistor in each pixel is simplified as follows,

$$\begin{matrix}{I}_{dd} ( x ) = μ {C}_{ox} \frac{W}{2 L} {( {V}_{gs} - {V}_{th} )}^{2} \\ = μ {C}_{ox} \frac{W}{2 L} {( {V}_{pixel} - {V}_{dd} ( x ) - {V}_{th} )}^{2} \\ = μ {C}_{ox} \frac{W}{2 L} {( 2 - ( 2 \cdot {10}^{- 6} {x}^{2} - {10}^{- 3} x + 7 ) - ( - 3 ) )}^{2} \\ = μ {C}_{ox} \frac{W}{2 L} {( - 2 + {10}^{- 3} x - 2 \cdot {10}^{- 6} {x}^{2} )}^{2} \\ \approx μ {C}_{ox} \frac{W}{2 L} ( 4 - ( 4 \cdot {10}^{- 3} x + 10 \cdot {10}^{- 6} {x}^{2} - 4 \cdot {10}^{- 9} {x}^{3} ) \\ = μ {C}_{ox} \frac{W}{2 L} 4 \cdot ( 1 - {10}^{- 3} x + 2.5 \cdot {10}^{- 6} {x}^{2} - {10}^{- 9} {x}^{3} ) .\end{matrix}$$

Since the brightness of an OLED is proportional to the current conducted thereby, the brightness of the pixels is the same when the current conducted thereby is the same. In other words, I_{dd}(x) needs to be a constant.

$$\frac{W}{L} ( 1 - {10}^{- 3} x + 2.5 \cdot {10}^{- 6} {x}^{2} - {10}^{- 9} {x}^{3} ) = \frac{{W}_{0}}{{L}_{0}}$$

W₀ and L₀ are respectively the channel width and channel length of the first driving transistor. If the variable L is fixed as L₀, then the channel length of all driving transistors is L₀. The channel width of the driving transistor at any location can be adjusted such that
W(x)·(1−10⁻³x+2.5·10⁻⁶x²−10⁻⁹x³)=W₀

Thus, the channel width of each driving transistor is

$$W ( x ) = \frac{{W}_{0}}{( 1 - {10}^{- 3} x + 2.5 \cdot {10}^{- 6} {x}^{2} - {10}^{- 9} {x}^{3} )} \qquad ( 1 )$$

As shown in FIG. 5, the thin and thick dashed curve, respectively, stands for the simulation results of the quadratic and cubic polynomial of the equation (1). The current no longer varies significantly with pixel location. The simulation results of the cubic polynomial even show that the current increases 0.67% despite of the decrease of V_{dd} power supply voltage with the pixel location. Thus, the method by the invention provides a display with reduced current variation between driving transistors thereof.

As shown in FIG. 4, the simulation shows the source voltages V_{dd}_{_{—}}₁, V_{dd}_{_{—}}₂, . . . , V_{dd}_{_{—}}_{N} corresponding to pixel location. It shows that the source voltage of the driving transistors T_{dr}_{_{—}}₁˜T_{dr}_{_{—}}_{N} changes gradually with the locations of the driving transistors. As shown in FIG. 5, the curve represents the driving current flowing through the OLED in each pixel and the driving current varies with the V_{dd} power supply voltage in each pixel. If there are 240 pixels in a column (N=240), the current in the first pixel is about 2.35 μA. For the 240^{th} pixel, the current drops to 2.2 μA. The current variation is about 6.58%, which is higher than the current variation with varying driving transistors.

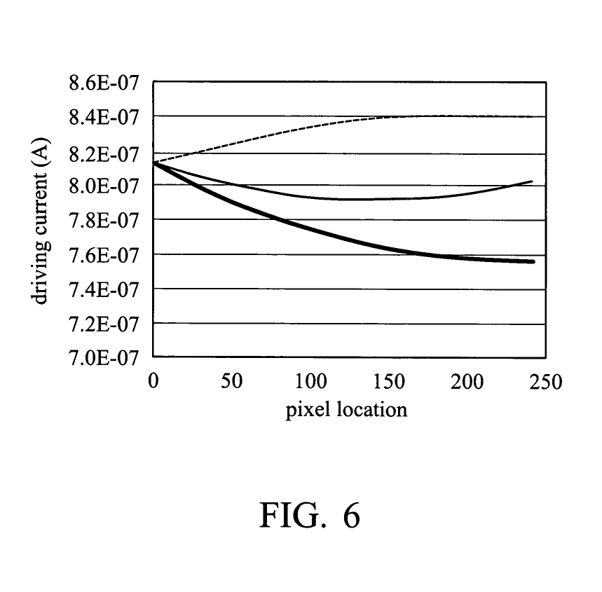

To confirm feasibility of the invention, current variation with pixel location at a different gray scale is simulated. Assuming that the pixel voltage of all pixels is 3V and each driving transistor in the same column is of the same channel size, the simulation results show that the current flowing through the OLED device in a conventional OLED display drops 7.18%, as shown by the thick curve in FIG. 6. However, if the V_{dd} voltage is represented as a cubic polynomial and the driving transistor size varies with the V_{dd} voltage according to one embodiment of the invention, then the current flowing through the OLED device increases 3.48% from the first to 240^{th} pixel, as shown by the dashed curve. Thus, it is confirmed that the method provided by the invention reduces current variation between driving transistors.

In addition, embodiments of the invention also provide an OLED panel. The OLED panel comprises a substrate and a pixel array formed thereon. Each pixel in the pixel array comprises a driving transistor to drive an OLED correspondingly, wherein not all of the driving transistors in the driving transistor array have the same channel size. At least two of the driving transistors in the pixel array are connected to the same power line.

Embodiments of the invention appropriately compensate voltage drops along a power line by changing channel sizes of the driving transistors along the same power line. Thus, the current flowing through the display device in each pixel is substantially the same. As a result, uniformity of a display is improved.

While the invention has been described by way of example and in terms of preferred embodiment, it is to be understood that the invention is not limited thereto. To the contrary, it is intended to cover various modifications and would be apparent to those skilled in the art. Therefore, the scope of the appended claims should be accorded the broadest interpretation so as to encompass all such modifications.

1. A method for manufacturing an electro-luminescence display, the method comprising:
forming a plurality of power lines on a substrate;
forming a plurality of driving transistors connected to the power lines, wherein the driving transistors in a column are connected to one of the power lines and not all of the channel sizes of the driving transistors in the column are the same; and
forming a plurality of electro-luminescence units, wherein each of the emitting units is electrically connected to a corresponding one of the plurality of driving transistors.

2. The method of claim 1, wherein the driving transistors are of sequentially different channel sizes along the power line.

3. The method of claim 2, wherein the driving transistors are of linearly different channel sizes along the power line.

4. The method of claim 1, wherein the driving transistors are of different channel lengths.

5. The method of claim 1, wherein the driving transistors are of different channel widths.

6. The method of claim 1, wherein the driving transistors are of different width/length ratios.

7. An electro-luminescence panel, comprising:
a substrate;
a plurality of power lines disposed on the substrate;
a plurality of driving transistors disposed on the substrate and electrically connected to the power lines, wherein the driving transistors in a column are connected to one of the power lines and not all of the channel sizes of the driving transistors in the column are the same; and
a plurality of electro-luminescence units disposed on the substrate, wherein each of the electro-luminescence units is electrically connected to a corresponding one of the plurality of driving transistors.

8. The electro-luminescence panel of claim 7, wherein the driving transistors are of sequentially different channel sizes along the power line.

9. The electro-luminescence panel of claim 8, wherein the driving transistors are of linearly different channel sizes along the power line.

10. The electro-luminescence panel of claim 7, wherein the display device is an electro-luminescence device.

11. The electro-luminescence panel of claim 10, wherein the electro-luminescence device is an organic light emitting diode (OLED).

12. The electro-luminescence panel of claim 7, wherein the driving transistors are of different channel lengths.

13. The electro-luminescence display of claim 7, wherein the driving transistors are of different channel widths.

14. The electro-luminescence display of claim 7, wherein the driving transistors are of different width to length ratios.
